(19) United States
(12) Patent Application Publication
(10) Pub. No.: US 2026/0103791 A1
(43) Pub. Date: Apr. 16, 2026

(54) SYSTEM AND METHOD FOR PROCESSING SUBSTRATE

(71) Applicant: Tokyo Electron Limited, Tokyo (JP)

(72) Inventors: Ronald Nasman, Albany, NY (US); Peter D'Elia, Albany, NY (US)

(21) Appl. No.: 18/914,919

(22) Filed: Oct. 14, 2024

(51) Int. Cl. C23C 14/56

(52) U.S. Cl. CPC C23C 14/566; C23C 14/568

(57) ABSTRACT

A method for processing a substrate includes dispensing a processing fluid onto the substrate in a processing chamber from an opening through an upper surface of the processing chamber and displacing the processing fluid in the processing chamber with a dry fluid injected through the opening as a wavefront pulse. The opening is near an edge of the substrate. The dry fluid displaces the processing fluid through a conduit opposite the opening.

### TECHNICAL FIELD

The present invention relates generally to semiconductor manufacturing, and, in particular embodiments, to a system and method for processing a substrate.

### BACKGROUND

Integrated circuits are formed by using planar processes in which an ultraclean, flat wafer of silicon is used as a substrate upon which a large number of identical devices are built by various oxidation, photolithography, removal, ion bombardment and deposition processes. Surface preparation before and after the processes is critical for the patterning of microelectronics devices since device performance, reliability and product yield of silicon circuits are critically affected by the presence of chemical contaminants and particulate impurities on the wafer surface.

A variety of dry and wet processes are currently used for cleaning semiconductor wafer surfaces. Dry cleaning processes include steps for wafer cleaning and wafer drying using a gas exposure. Wet cleaning processes include a series of steps of immersing or spraying the wafers with a variety of liquids, including chemical solutions and rinse solutions. These wet and dry processes may be performed within a wide variety of processing chambers and systems.

Spin chambers are used to clean one or more surfaces of a semiconductor wafer using wet and dry processes. A spin chamber uses a spin chuck and drive mechanism (e.g., a stepper motor) to rotate or spin a semiconductor wafer mounted onto the spin chuck, at least one liquid nozzle for dispensing one or more liquids onto the wafer surface(s) while the semiconductor wafer is spinning, and a large cup for capturing the liquids that are ejected from the wafer surface(s) by the centrifugal forces generated during rotation of the spin chuck.

A variety of cleaning processes may be performed within a spin chamber. In one example cleaning process, a chemical solution is dispensed onto a surface of the semiconductor wafer, while the semiconductor wafer is spinning, to clean the wafer surface. After the cleaning step, a rinse solution is dispensed onto the wafer surface, while the semiconductor wafer is spinning, to remove the chemical solution and rinse the wafer surface. After the rinse step, wafer rotation may continue to spin-dry the wafer surface. In some cases, a puddle process may be performed between the wafer cleaning and rinse steps. In a puddle process, a chemical solution is dispensed onto the wafer surface while wafer rotation is stopped (or significantly slowed) to enable a puddle of the chemical solution to form on the wafer surface. In some cases, the puddle may reduce the amount of chemical needed to clean the wafer surface. Some variations of the puddle process include dispensing a chemical solution onto the wafer and moving the wafer with puddle to a separate chamber for a supercritical dry process, which may be useful for reducing or eliminating pattern collapse on fine features.

Conventional wet cleaning processes and processing chambers have several disadvantages. For example, spin chambers tend to be large and complicated, due to the need for a spin chuck, drive mechanism and large liquid capturing cup. In addition, current wet cleaning processes utilized within spin chambers typically require a large amount of ultrapure chemicals. Pattern collapse may occur due to high surface tension of solvents at supercritical pressures. The high cost and large amount of ultrapure chemicals required in current wet cleaning processes, and the treatment of hazardous waste resulting from such processes, together with its incompatibility with the advanced concepts of integrated processing such as cluster tooling, require new processing chambers and methods that are less affected by these limitations.

There is a strong need for an improved processing system and method to reduce chemical consumption, reduce processing steps, and increase equipment utilization without losing the effectiveness of the process. In particular, there is a need for improved methods for ultraclean surface preparation including wet and dry processes.

### SUMMARY

In accordance with an embodiment, a method for processing a substrate includes: dispensing a processing fluid onto the substrate in a processing chamber from an opening through an upper surface of the processing chamber, the opening near an edge of the substrate; and displacing the processing fluid in the processing chamber with a dry fluid injected through the opening as a wavefront pulse, the dry fluid displacing the processing fluid through a conduit opposite the opening.

In accordance with another embodiment, a method for processing a substrate includes: dispensing an etch chemistry into a processing space, the processing space holding the substrate; displacing the etch chemistry through the processing space with a wavefront pulse of deionized water; displacing the deionized water through the processing space with a wavefront pulse of isopropyl alcohol (IPA); and displacing the IPA through the processing space with a wavefront pulse of liquid carbon dioxide (CO2).

In accordance with yet another embodiment, a processing system includes: a processing chamber including an opening in an upper surface of the processing chamber, the opening being coupled to respective supplies of a processing fluid and a dry fluid, the processing chamber being configured to: receive a substrate in a processing space within the processing chamber; dispense a processing fluid over the substrate from the opening; and displace the processing fluid with a wavefront pulse of a dry fluid from the opening.

It is to be understood that both the foregoing general description and the following detailed description are exemplary and explanatory only and are not restrictive of the disclosure, as claimed.

### BRIEF DESCRIPTION OF THE DRAWINGS

FIG. 1 illustrates an example processing system for processing of a substrate;

FIGS. 2-7 illustrate cross-sectional views of a processing system during intermediate stages of a method for wavefront processing of a substrate, in accordance with some embodiments;

FIG. 8 illustrates a cross-sectional view of a processing system during an intermediate stage of another method for wavefront processing of a substrate, in accordance with some embodiments;

FIGS. 9-10 illustrate cross-sectional views of a processing system during intermediate stages of a method for wavefront processing of a substrate including treatment with a supercritical fluid, in accordance with some embodiments;

FIGS. 11, 12, 13A, 13B, 13C, 14A, and 14B illustrate systems and methods for avoiding gas introductions or meniscus formation, in accordance with some embodiments;

FIG. 15 illustrates a process flow chart diagram of a method for processing a substrate, in accordance with some embodiments; and

FIG. 16 illustrates a process flow chart diagram of a method for processing a substrate, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

According to one or more embodiments of the present disclosure, this application relates to methods of wet and dry processing of a substrate, such as a semiconductor wafer. In conventional semiconductor manufacturing processes, supercritical carbon dioxide (CO₂) is often used for cleaning and drying wafers. The present disclosure relates to systems and methods for cleaning and drying semiconductor wafers using supercritical or near-supercritical carbon dioxide (CO₂). In various embodiments, a wavefront cleaning chamber enables single-chamber processing of wafers through multiple fluid phases, improving throughput and reducing equipment complexity. The chamber design allows for precise control of fluid displacement, pressure, and temperature to achieve improved cleaning and drying results while reducing or eliminating pattern collapse in fine semiconductor structures, all performed within a single chamber. The chamber design may further allow all high pressure gases (e.g., N₂) and fluids (e.g., liquid CO₂) to be delivered directly from cylinders rather than from tool compressors, leading to a significant reduction in product cost and complexity.

In one or more embodiments, a small-volume chamber incorporates a wavefront fluid delivery system that enables uniform displacement of process fluids across the wafer surface. This approach allows for efficient transitions between etch chemistries, rinse solutions, and drying fluids while maintaining a controlled environment throughout the process. The wavefront design facilitates the use of lower volumes of CO₂ compared to conventional supercritical drying techniques, reducing operational costs and environmental impact.

Various embodiments provide methods for pressurizing the chamber using inert gases such as nitrogen (N₂) prior to introducing liquid CO₂. This pre-pressurization step can help reduce the overall pressure requirements for achieving supercritical or near-supercritical conditions, potentially allowing for lighter and less complex chamber designs. The disclosed techniques also enable efficient recovery and recycling of process fluids such as isopropyl alcohol (IPA), further improving cost-effectiveness and sustainability.

In some embodiments, the system allows for precise control of the transition between liquid and supercritical CO₂ phases, enabling reduction of surface tension effects to prevent pattern collapse in increasingly fine semiconductor structures. The ability to operate at pressures near, but not necessarily exceeding, the critical point of CO₂ provides flexibility in balancing cleaning effectiveness, pattern stability, and equipment requirements.

The following detailed description provides further explanation of these and other embodiments, referencing the accompanying drawings to illustrate specific implementations and configurations of the disclosed systems and methods.

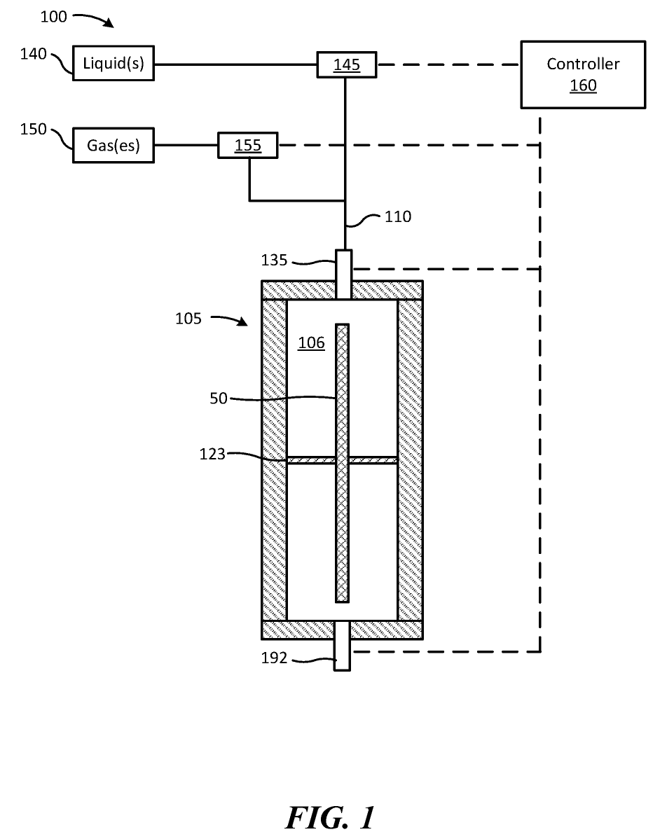

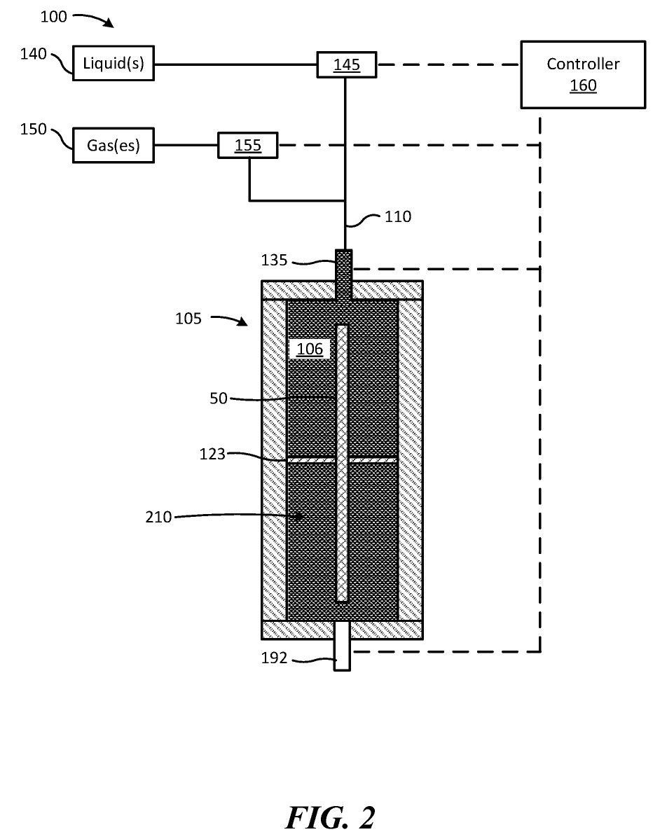

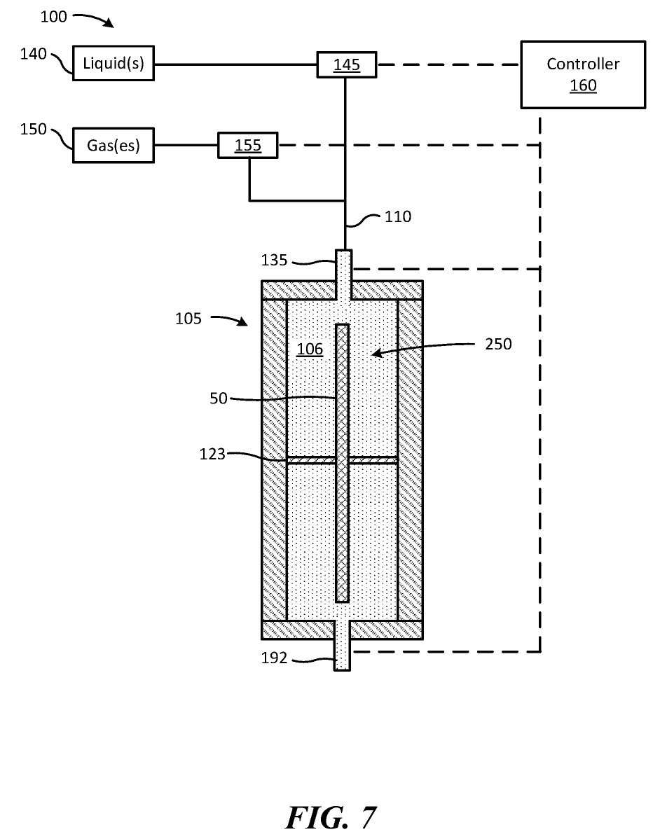

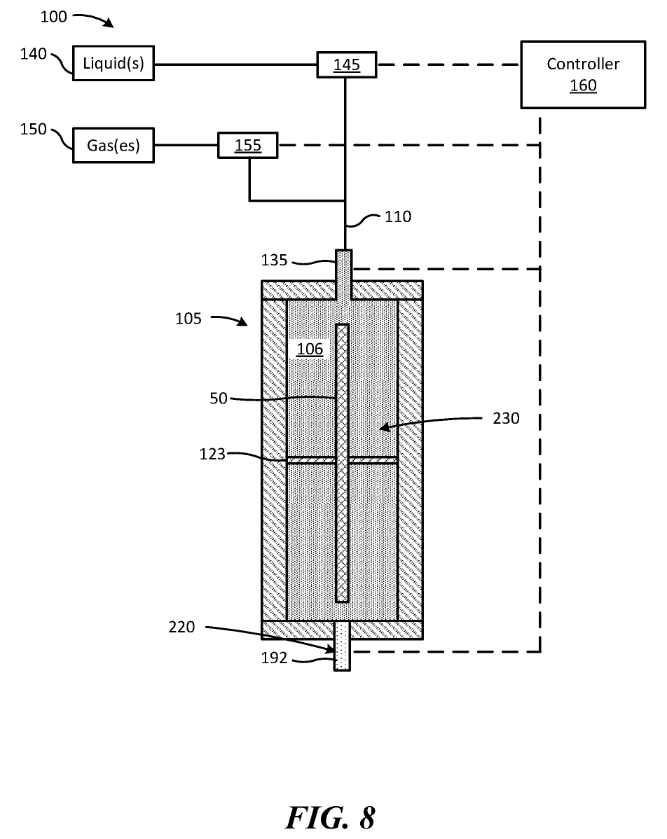

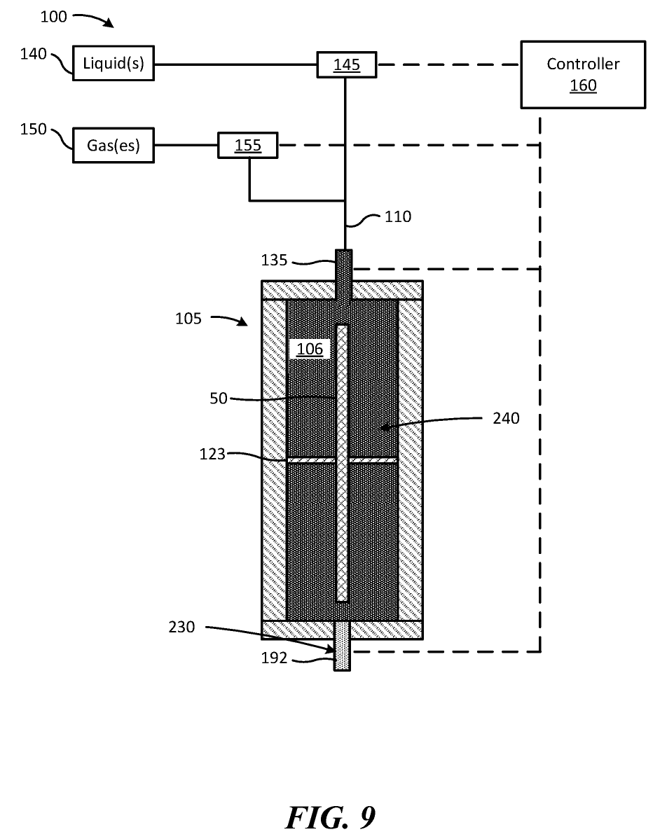

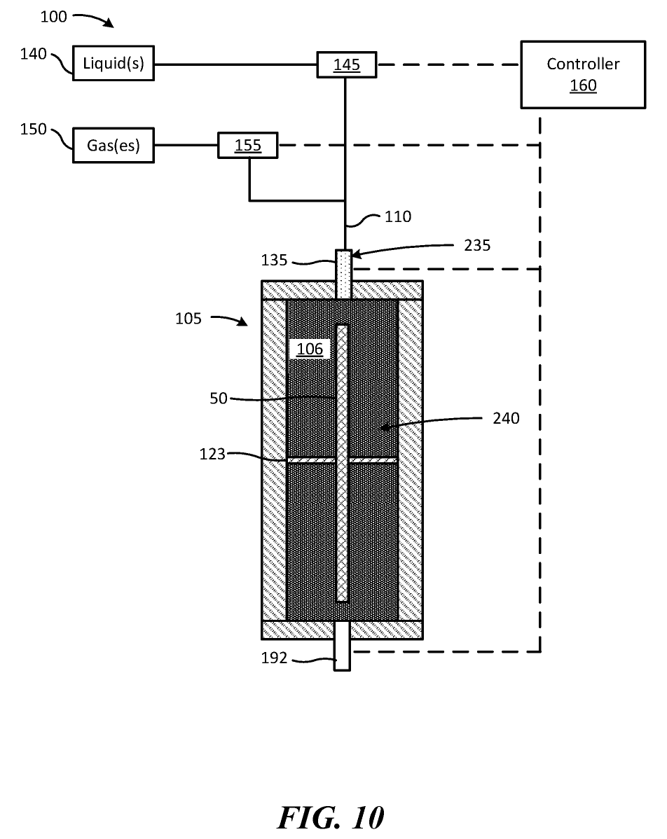

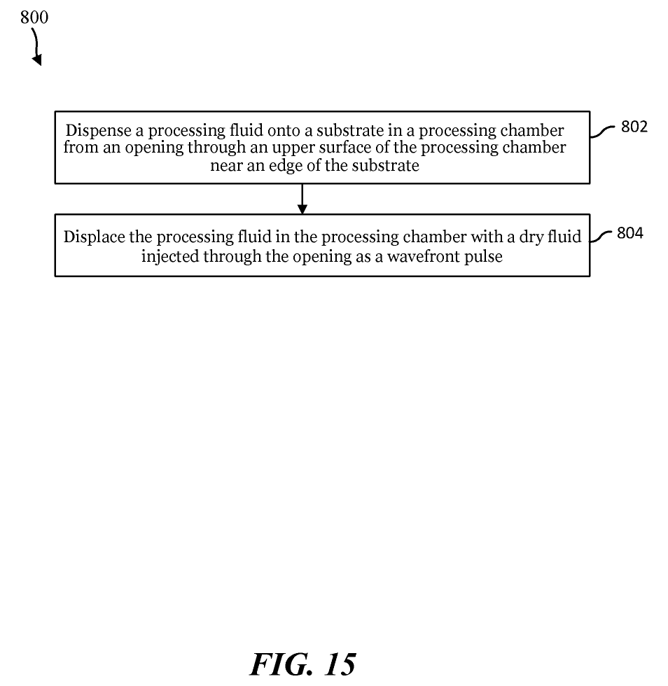

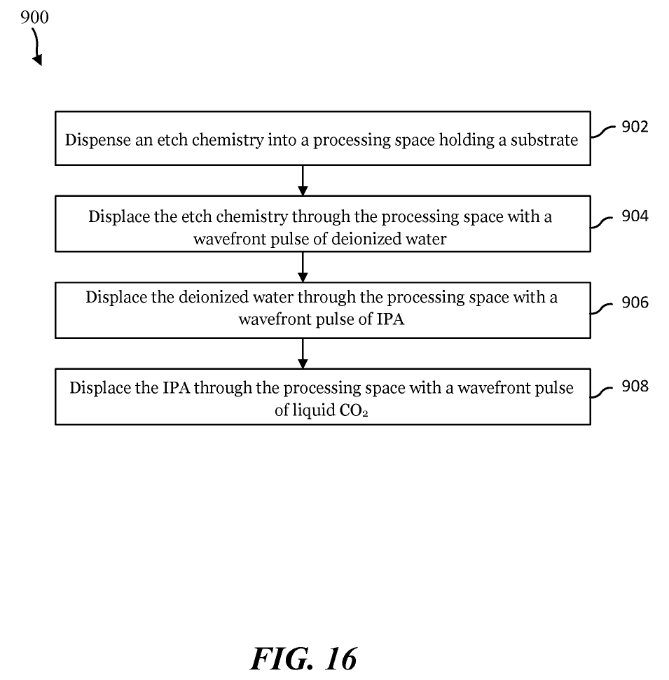

Embodiments of the disclosure are described in the context of the accompanying drawings. An example of a processing chamber for wet and dry processing of a substrate will be described using FIG. 1. Embodiments of methods for wavefront processing of a substrate will be described using FIGS. 2-7. Embodiments of another method for wavefront processing of a substrate will be described using FIG. 8. Embodiments of methods for wavefront processing of a substrate including treatment with a supercritical fluid will be described using FIGS. 9-10. Embodiments of systems and methods for avoiding gas introductions or meniscus formation will be described using FIGS. 11, 12, 13A, 13B, 13C, 14A, and 14B. Embodiments of methods for processing a substrate will be described using FIGS. 15 and 16.

FIG. 1 schematically illustrates a cross-sectional view of an example processing system 100 (also referred to as a substrate processing system or a wafer processing system) for processing of a substrate. The processing system 100 illustrated by FIG. 1 includes a processing chamber 105 in which a substrate 50 (e.g., a semiconductor wafer) is processed. The processing chamber 105 includes a processing space 106, in which the substrate 50 may be held by one or more suitable structure(s) 123. In various examples, the one or more structure(s) 123 for supporting the wafer include a plurality of pins that extend through sidewalls of the processing chamber 105 into the processing space 106 and support the substrate 50 from the sides, as shown in FIG. 1. In various examples, the one or more structure(s) 123 for supporting the substrate 50 include wafer support mechanisms (e.g., a wafer tray or wafer chamber). In some examples, the processing chamber 105 is oriented to hold the substrate vertically, so that a longitudinal axis of the substrate 50 is parallel with a vertical direction. However, the processing chamber 105 may have any suitable orientation.

In some examples, at least one opening 135 passes through an upper surface of the processing chamber 105 into the processing space 106. When processing a substrate 50 mounted within the processing space 106, the at least one opening 135 passing through the upper surface of the processing chamber 105 may be in fluid flow communication with at least one processing fluid (e.g., a liquid and/or a gas), such as by being coupled with a supply line 110 (also referred to as a supply tube or a dog leg supply tube), and may be configured to direct the at least one processing fluid into the processing space 106 below the upper surface of the processing chamber 105 for processing one or more surfaces of the substrate 50. In some examples, the at least one opening 135 includes a respective nozzle (e.g., an elongated nozzle) for dispensing a liquid onto the substrate 50 such that the liquid flows in a lateral direction across the surface of the substrate 50 with uniform flow velocity across a direction perpendicular to the lateral direction. As such, uniform fluid flow across a substrate surface may be achieved without spinning the substrate 50, as further described in U.S. Patent Application No. 18/436,920, which is hereby incorporated by reference in its entirety. Although the at least one opening 135 is illustrated as passing through the upper surface of the processing chamber 105, the at least one opening 135 may have any suitable location through any suitable chamber wall of the processing chamber 105. In some embodiments, the uniform fluid flow is performed as a cross flow across the processing space 106 in a linear direction.

In some examples, the at least one opening 135 passing through the upper surface of the processing chamber 105 is in fluid flow communication with one or more supply lines (e.g., a supply line 110 coupled with the at least one opening 135) for one or more liquids 140 and liquid supply valves 145 and for one or more gases 150 and gas supply valves 155, as shown further in FIG. 1.

The processing system 100 illustrated by FIG. 1 further includes a drainage system for directing processing fluids out of the processing chamber 105. According to one example, the drainage system includes one or more conduit(s) 192 that is in fluid communication with, and downstream from, the processing space 106. As illustrated by FIG. 1, the conduit 192 passes through a lower surface of the processing chamber 106 opposite the opening 135. However, the conduit 192 may have any suitable location through any suitable chamber wall of the processing chamber 105.

In some examples, the processing system 100 includes a controller 160 that is coupled to the liquid supply valves 145 and gas supply valves 155 for selectively providing the one or more liquids 140 and/or the one or more gases 150 through the supply line 110 to the processing space 106 within the processing chamber 105. A wide variety of liquids and gases may be selectively provided to the processing space 106 depending on the process, or process step, being performed within the processing chamber 105. The controller 160 may be further coupled with valves in the one or more opening(s) 135 and conduit(s) 192 to control fluids and/or gases entering and/or exiting the processing chamber 105.

During a cleaning process, for example, the controller 160 may supply control signals to the liquid and gas supply valves 145/155 to selectively provide a cleaning solution and/or a rinse solution to the processing space 106 for cleaning and/or rinsing the substrate 50. Examples of cleaning solutions include, but are not limited to, an ammonia/peroxide mixture (APM), a hydrochloric/peroxide mixture (HPM) and a sulfuric peroxide mixture (SPM). Examples of rinse solutions include, but are not limited to, deionized (DI) water and isopropyl alcohol (IPA). Other cleaning solutions and rinse solutions may also be utilized. After cleaning and/or rinsing the surface(s) of the substrate 50, the controller 160 may supply control signals to the liquid and gas supply valves 145/155 to selectively provide a gas (such as, but not limited to, air, nitrogen, carbon dioxide, or the like) to the processing space 106 to remove any remaining liquid the wafer surface(s), thereby drying the wafer surface(s). The gas may be vented to outside the processing chamber through the opening(s) 192 or any other suitable opening or vent that couples the processing space 106 to the outside of the processing chamber 105. In some examples, the controller 160 supplies control signals to the liquid and gas supply valves 145/155 to selectively provide a low surface tension liquid (such as IPA) to the processing space 106, before the cleaning step is performed, to pre-wet the surface of the substrate 50.

The processing system 100 and processing chamber 105 illustrated by FIG. 1 is included as a non-limiting example for illustrative purposes. Although the processing system 100 is illustrated as processing a single substrate 50, in various examples the processing system 100 is a batch processing system that can be used to simultaneously process a plurality (or batch) of semiconductor substrates at a time. Further examples of suitable processing chambers for embodiments of the current disclosure may be found in U.S. Patent Application No. 18/436,920, which is above incorporated by reference in its entirety.

FIGS. 2 through 7 illustrate cross-sectional views of a processing system (e.g., the example processing system 100) during intermediate stages of methods for wavefront processing of a substrate, in accordance with some embodiments. Using wavefront processing for etching, purging, rinsing, and drying may allow for single chamber processing of a substrate, improving throughput. Additionally, using a process chamber with a small volume may reduce the amount of carbon dioxide (CO₂) used in the process. Although FIGS. 2 through 7 describe an example of wavefront processing of a substrate including an etch step, a purge step, a rinse step, and a drying step, wavefront processing may be performed for any process involving applying liquids, gases, and/or supercritical liquids to a substrate, and all such wavefront processing is within the scope of the disclosed embodiments.

In FIG. 2, an etch chemistry 210 enters the processing space 106 through the opening 135. The etch chemistry 210 is introduced in a manner that creates a wavefront through the processing space 106, such as from a top portion of the processing space 106 to a bottom portion of the processing space 106. In some embodiments, the wavefront has a velocity of about 1 m/s. This wavefront technique may be advantageous for causing the etch chemistry 210 to fill the chamber 102 uniformly, which may reduce the risk of trapped air pockets or uneven chemical distribution across the surface of the substrate 50. In various embodiments, the etch chemistry 210 comprises hydrochloric acid (HCl), ammonium hydroxide, hydrogen peroxide, hydrogen bromide (HBr), the like, or a combination thereof. However, any suitable wet etchants may be used for the etch chemistry 210.

Once the processing space 106 is filled, the flow of the etch chemistry 210 may be stopped to allow the etching process to complete. In some embodiments, the flow may be maintained or reintroduced as pulses to refresh the etch chemistry 210 in the processing space 106 during the etching process. Although the direction of flow of the etch chemistry 210 is illustrated as being from the opening 135 on the top of the processing space 106, the flow can be in any suitable direction from any suitable opening.

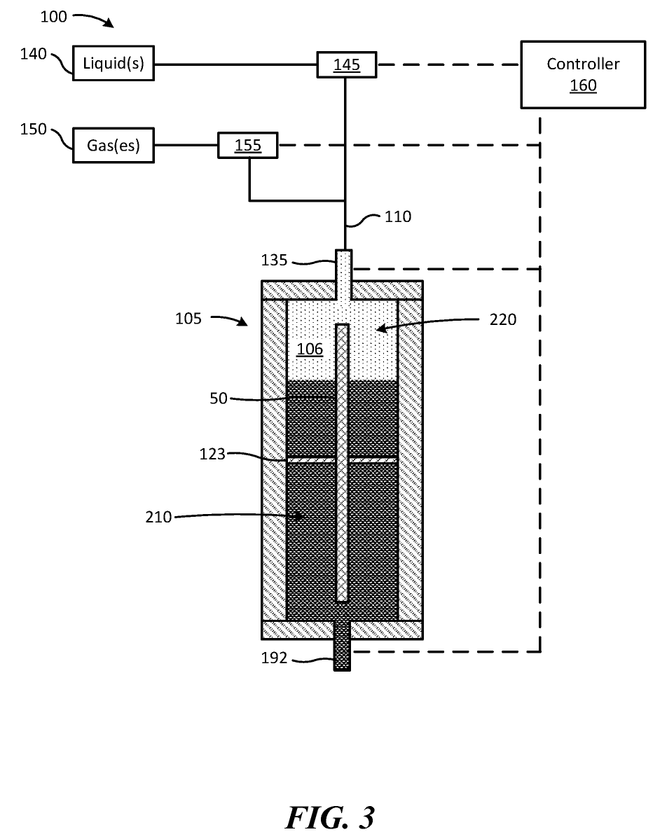

Next, in FIG. 3, a purge step is performed to remove the etch chemistry 210 from the processing space 106 with a purge liquid 220. In various embodiments, the purge liquid 220 is deionized (DI) water. However, any suitable composition may be used for the purge liquid 220. The purge liquid 220 is driven into the processing space 106 as a wavefront pulse to displace the etch chemistry 210 and thereby stop the etching process. In some embodiments, the wavefront has a velocity of about 1 m/s. As illustrated by FIG. 3, the purge liquid 220 enters the processing space 106 through the opening 135. The etch chemistry 210 may be removed from the processing space 106 through ta conduit 192 that is opposite the opening 135. Subsequently, the etch chemistry 210 may be recovered for reuse and/or recycling.

In some embodiments, the processing space 106 is fully filled with the purge liquid 220. The flow of the purge liquid 220 may be stopped temporarily to allow eddy zones to diffuse into the flow and then purged out when the flow of the purge liquid 220 is reinstated for a second purge step with the purge liquid 220. This sequence may be repeated for any suitable number of steps. In some embodiments, the etch chemistry 210 is displaced by a short wavefront pulse of the purge liquid 220 that is long or wide enough in duration to reduce or prevent diffusion of the etch chemistry 210 through the purge pulse to a processing fluid delivered in the next step.

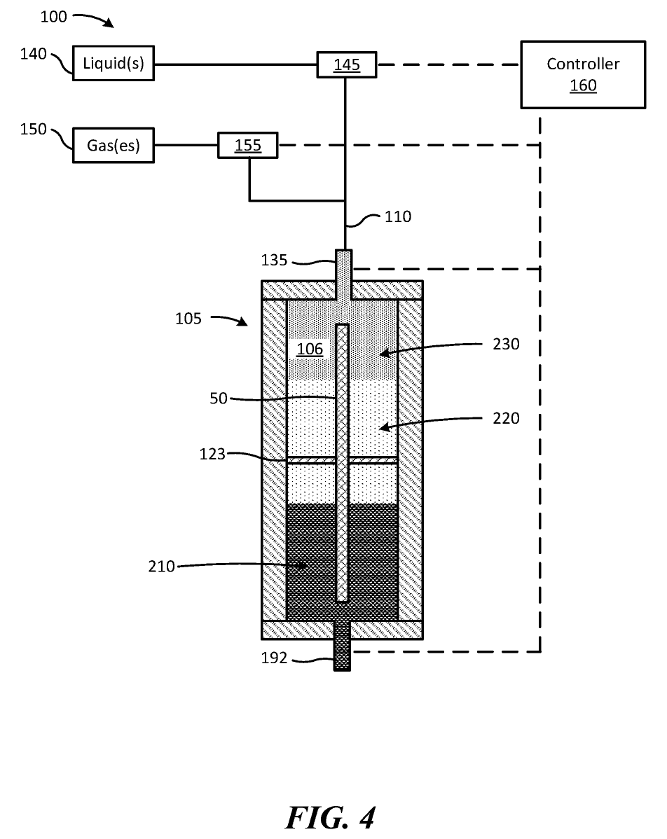

In FIG. 4, following from FIG. 3, a processing fluid 230 (also referred to as a rinsing fluid) is injected into the processing space 106 through the opening 135. In various embodiments, the processing fluid 230 is a cleaning solution and/or a rinse solution used for cleaning and/or rinsing at least one surface of the substrate 50, such as a low surface tension fluid (e.g., isopropyl alcohol (IPA) or the like). The processing fluid 230 displaces, as a wavefront pulse, the purge liquid 220 and any remaining portions of the etch chemistry 210, which may be removed from the processing space 106 through the conduit 192. In some embodiments, the wavefront has a velocity of about 1 m/s. Subsequently, the purge liquid 220 may be recovered for reuse and/or recycling. In some embodiments (see below, FIG. 8), the processing fluid 230 completely fills the processing space 106. In other embodiments, portions of the purge liquid 220 and the etch chemistry 210 remain in the processing space 106 and are displaced by the injection of the processing fluid 230.

Purge liquid 220 (e.g., DI water) remaining in fine features etched into the substrate 50 may diffuse into the processing fluid 230. In some embodiments, the purge liquid 220 (and any remaining portion of the etch chemistry 210) is displaced by a short wavefront pulse of the processing fluid 230 that is long or wide enough in duration to reduce or prevent diffusion of the purge liquid 220 through the purge pulse to a dry fluid delivered in the next step.

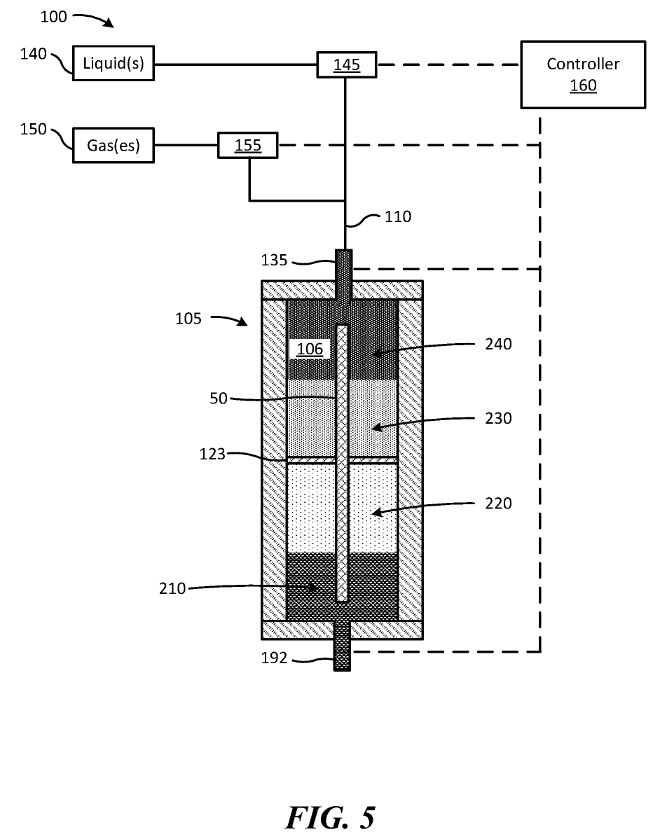

Next, in FIG. 5, the processing fluid 230 (along with any remaining portions of the purge liquid 220 and the etch chemistry 210) are displaced by the injection of a wavefront pulse of dry fluid 240. In some embodiments, the wavefront has a velocity of about 1 m/s. In some embodiments, the processing space 106 is first pressurized by the injection of a pressurizing gas 235 (not illustrated), which is then followed by an injection of the dry fluid 240 through the opening 135.

In various embodiments, the pressurizing gas 235 comprises carbon dioxide (CO₂), nitrogen (N₂), the like, or a combination thereof. In an embodiment, the pressurizing gas 235 is CO₂. In another embodiment, the pressurizing gas 235 is N₂. The pressurizing gas 235 may be provided to the processing space 106 through the opening 135. However, the pressurizing gas 235 may be provided to pressurize the processing space 106 through any suitable inlets and/or valves. In some embodiments, the pressurizing gas 235 is used to pressurize the processing space 106 to a pressure of 4.5 MPa or greater, which is sufficient to maintain the dry fluid 240 (e.g., CO₂) in a liquid phase at room temperature (such as around 25 ºC). In other embodiments, the pressurizing gas 235 is used to further pressurize the processing space 106 to the critical pressure of the dry fluid 240 (see below, FIGS. 9-10), which may be useful for further reducing surface tension on fine features of the substrate 50 by bringing the dry fluid 240 to a supercritical state.

Next, pressurized dry fluid 240 is injected into the processing space 106, such as through the opening 135. The dry fluid 240 displaces the processing fluid 230 and any remaining portions of the purge liquid 220 and the etch chemistry 210. These may be removed from the processing space 106 through the conduit 192, which is opposite the opening 135 in some embodiments. The conduit 192 may be sufficiently restrictive to maintain the pressure in the processing space 106 so that the dry fluid 240 remains under sufficient pressure to stay as a liquid. Subsequently, the processing fluid 230 may be captured or recovered for reuse and/or recycling.

In some embodiments (see below, FIGS. 9-10), the dry fluid 240 completely fills the processing space 106. In other embodiments, portions of the processing fluid 230, the purge liquid 220, and/or the etch chemistry 210 remain in the processing space 106 at a same time and are displaced by the injection of the dry fluid 240.

The dry fluid 240 (e.g., liquid CO₂) may have a lower surface tension than the processing fluid 230 (e.g., IPA), which may reduce the risk of pattern collapse on the substrate 50. Displacing the processing fluid 230 (e.g., IPA) with the dry fluid 240 allows for recovery and recycling of the processing fluid 230, further enhancing process efficiency. Drying the substrate 50 with the dry fluid 240 (rather than a supercritical fluid) may allow for operation at lower pressures (e.g., in a range of 4.5 MPa to 6.5 MPa, or 4.5 MPa to 5.5 MPa) and at room temperature (e.g., around 25 ºC), potentially increasing throughput and reducing equipment costs.

The lower surface tension of the dry fluid 240 (e.g., liquid CO₂) compared to the processing fluid 230 (e.g., IPA) may reduce the risk of pattern collapse in delicate semiconductor structures on the substrate 50. For example, liquid CO₂ has a surface tension of 1.37 mN/m at 20 ºC and 0.59 mN/m at 25 ºC. Additionally, introducing the dry fluid 240 in a liquid phase (rather than, e.g., in a supercritical condition) may allow less of the dry fluid 240 to be used, thereby saving costs.

In some embodiments, the dry fluid 240 (e.g., liquid CO₂) is kept below a supercritical state, which may allow the processing chamber 105 to operate at lower pressures, thereby reducing cost. For example, liquid CO₂ at room temperature (e.g., around 25 ºC) needs to be at a pressure above 4.5 MPa, while IPA does not reach a supercritical state until 235.6 ºC at 5.37 MPa. By inserting the dry fluid 240 without bringing it to a supercritical state, the pressure in the processing chamber 105 may be kept at 5 MPa or less, such as in a range of 4.5 MPa to 5 MPa, while adding the dry fluid 240 and recovering the processing fluid 230, thereby allowing the processing chamber 105 to have a lower tolerance for high pressures. As tolerances may be, for example, three times the desired pressure, the processing chamber 105 could have a tolerance of 15 MPa. This can reduce costs by allowing for using a lighter chamber structure, fewer seal problems, and generally leading to a significant reduction in product complexity and resulting costs. Additionally, the process of the dry fluid 240 injection may be performed at room temperature, so additional heat input may be avoided.

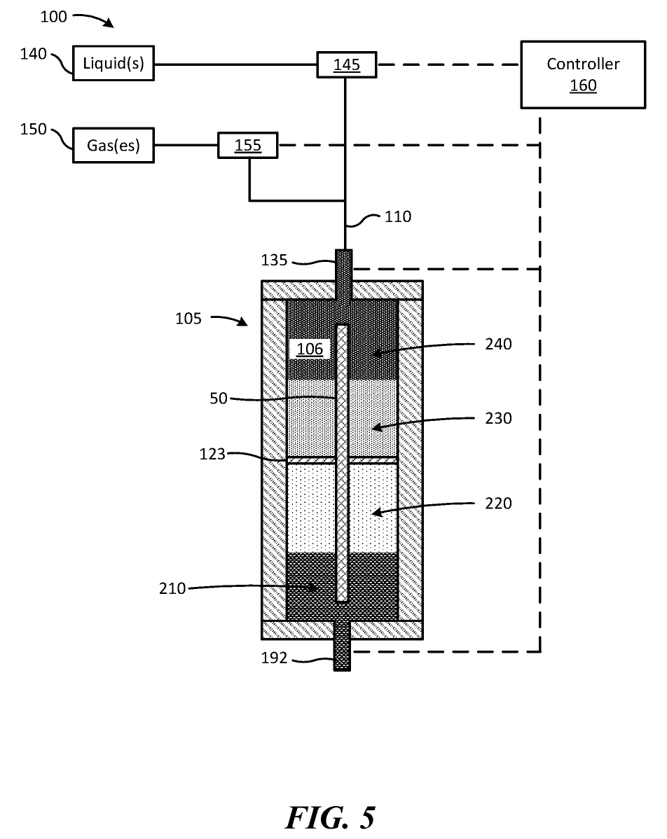

In FIG. 6, following from FIG. 5, a purging gas 250 is injected into the processing space 106 to displace the dry fluid 240 from the processing space 106. In various embodiments, the purging gas 250 is injected into the processing space 106 through the opening 351. The dry fluid 240 is completely drained from the processing space 106 under a high pressure (e.g., a pressure in a range of 4.5 MPa to 6.5 MPa, or 4.5 MPa to 5.5 MPa) to maintain the low surface tension environment and thereby reduce the risk of pattern collapse in delicate semiconductor structures on the substrate 50. The dry fluid 240, as well as any other fluids previously or subsequently removed from the processing space 106, may exit into a pressure managed environment to maintain either a liquid or a supercritical state. In some embodiments, the purging gas 250 comprises nitrogen (N₂), carbon dioxide (CO₂), the like, or a combination thereof.

In an embodiment, the purging gas 250 is N₂. Using nitrogen (N₂) gas to displace the dry fluid 240 from the processing space 106 instead of CO₂ may be advantageous by reducing the amount of CO₂ used, which can be beneficial for reducing costs and environmental impact. For example, CO₂ is a greenhouse gas, while N₂ is not a greenhouse gas; in fact, N₂ is more prevalent in the atmosphere and can be isolated and provided as a gas supply at a lower cost. CO₂ feed stock is hydrocarbon or ammonia based, while the feed stock for N₂ is atmospheric air, allowing for onsite production on demand, which can further reduce cost. High purity N₂ cylinders and tanks are usually charged to a higher pressure (23.6 MPa) as compared to CO₂ (5.9 MPa) which may be better suited to this specific use case due to the pressure required. N₂ chamber pressurization with the chamber filled with a liquid (e.g., liquid CO₂), which, unlike a gas, is minimally compressible, can be performed with only a small amount of N₂. As such, facility delivered N₂ is a viable option for this method. Furthermore, N₂ pressurization can be done in the supply line, if properly configured, so that the N₂ remains outside the processing chamber 105. In some embodiments, this supply line is then be valved off and vented independently of the chamber so that the introduction of N₂ to the processing chamber 105 may be greatly limited.

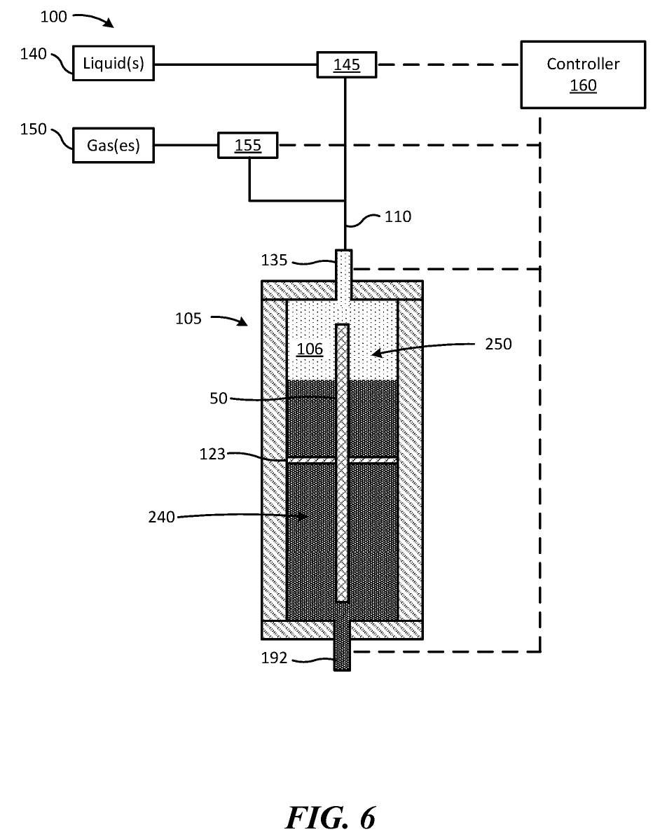

Next, in FIG. 7, the purging gas 250 completely fills the processing space 106. The high pressure of the purging gas 250 has driven out the dry fluid 240 and any remaining portions of the processing fluid 230, the purge liquid 220, and the etch chemistry 210 from the processing space 106, which may have been removed through, for example, the conduit 192.

After the purging gas 250 fills the processing space 106, the processing chamber 105 may be depressurized and the purging gas 250 vented out (in other words, released from the processing chamber 105), such as through the conduit 192. However, any valves and/or gas outlets may be used to vent the purging gas 250 out of the processing chamber 105. In some embodiments, the substrate 50 is then be removed from the processing chamber 105. In other embodiments, additional liquids and/or gases may be injected into the processing chamber 105 in order to perform additional wet and/or dry processes on the substrate 50.

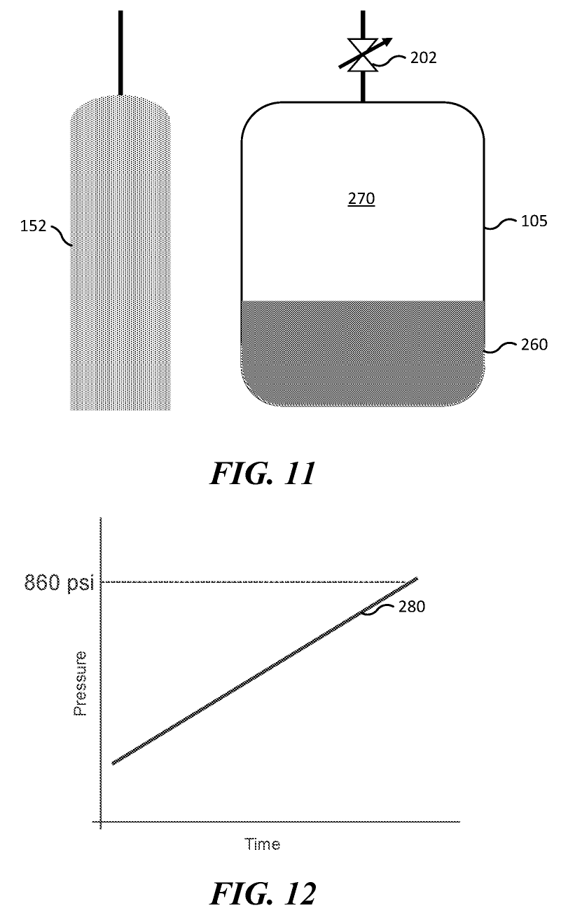

FIG. 8 illustrates a cross-sectional view of the processing system 100 during an intermediate stage of another method for wavefront processing of a substrate, in accordance with some embodiments. FIG. 12 follows from FIG. 3 but illustrates an embodiment in which the processing fluid 230 completely fills the processing space 106. The flow of the processing fluid 230 may be stopped temporarily to allow eddy zones to diffuse into the flow and then purged out when the flow of the processing fluid 230 is reinstated for a second purge step with the processing fluid 230. This sequence may be repeated for any suitable number of steps.

FIGS. 9-10 illustrate cross-sectional views of the processing system 100) during intermediate stages of methods for wavefront processing of a substrate including treatment with a supercritical fluid, in accordance with some embodiments. FIG. 9 follows from either FIG. 5 or FIG. 8, in which the processing space 106 is filled with a dry fluid 240 (e.g., liquid CO₂) that is in a liquid phase due to pressurization and temperature conditions in the processing space (e.g., under a pressure of 4.5 MPa or greater due to pressurization with a pressurizing gas 235 and at room temperature, such as around 25 ºC). The dry fluid 240 displaces the processing fluid 230 and any remaining portions of the purge liquid 220 and the etch chemistry 210. These may be removed from the processing space 106 through the conduit 192 that is sufficiently restrictive to maintain the pressure in the processing space 106 so that the dry fluid 240 remains under sufficient pressure to stay as a liquid. Subsequently, the processing fluid 230 may be captured or recovered for reuse and/or recycling.

Because the processing fluid 230 is displaced from the processing chamber rather than dissolved, a subsequent supercritical state of the dry fluid 240 may be simplified. For example, there may be no need to manage a supercritical state with a mixture of IPA with CO₂ as the IPA dissolves. By inserting the dry fluid 240 without bringing it to a supercritical state, the pressure in the processing chamber 105 may be kept at 5 MPa or less, such as in a range of 4.5 MPa to 5 MPa, while adding the dry fluid 240 and recovering the processing fluid 230, thereby allowing the processing chamber 105 to have a lower tolerance for high pressures. As tolerances may be, for example, three times the desired pressure, the processing chamber 105 could have a tolerance of 15 MPa, which could reduce costs.

Next, in FIG. 10, the dry fluid 240 is brought to a supercritical state to become a supercritical fluid 242. In some embodiments, pressure in the processing space 106 is increased by additional supply of the pressurizing gas 235 (e.g., CO₂ or N₂) and temperature is increased to bring the dry fluid 240 to a supercritical condition. For example, liquid CO₂ may be brought to supercriticality by increasing the temperature to 30.98 ºC or above and increasing the pressure to 7.38 MPa or above. The processing chamber 105 may be pressurized with gas through the opening 135 and have temperature increased by one or more heating element(s) of the top plate 115 and/or the bottom plate 110, as described above with respect to FIG. 1. However, any suitable methods or mechanisms may be used to adjust the temperature and pressure in the processing chamber 105 to bring the dry fluid 240 to a supercritical condition.

Subsequently, the pressurizing gas 235 may be vented while temperature in the processing space 106 is maintained with added heat input in order to prevent the supercritical fluid 242 from reverting out of the supercritical state to a liquid state. In some embodiments, the processing space 106 and its contents may have a higher initial temperature (for example, significantly greater than 31 ºC) in order to maintain the temperature above 31 ºC during the supercritical processing step.

Using a supercritical fluid to treat the substrate 50 may be advantageous to improve substrate drying and avoiding pattern collapse that sometimes occurs when using a processing fluid (e.g., IPA) to dry substrate surfaces. Since supercritical fluids have zero surface tension, pattern collapse may not occur when the wafer is dried in a supercritical fluid environment. Bringing the dry fluid 240 to supercriticality in the processing chamber 105 allows for a full processing of the substrate 50 (e.g., a treatment such as a rinse with the processing fluid 230) and a subsequent supercritical fluid dry treatment in the same processing chamber. The supercritical dry process may allow for uniform clearing of the processing chamber 105 after processing.

In some embodiments, the supercritical fluid 242 is subsequently purged from the processing chamber 105 using similar methods as used for the purging of the dry fluid 240 (e.g., displacing the supercritical fluid 242 with a purging gas 250 and subsequently venting the purging gas) as described above with respect to FIGS. 8-11, and the details are not repeated herein. However, any suitable method may be used to remove the supercritical fluid 242 from the processing chamber 105. For example, the processing chamber 105 may be depressurized and the supercritical fluid 242 may be vented from the processing chamber 105 in a gaseous phase (e.g., as gaseous CO₂).

FIGS. 11, 12, 13A, 13B, 13C, 14A, and 14B illustrate embodiments of a system and method for displacing a processing fluid 230 with a dry fluid 240 while avoiding gas introductions or meniscus formation. FIG. 11 illustrates a cross-sectional view of a simplified diagram of the processing system 100, which includes a processing chamber 105 coupled with one or more gas supplies 152 (e.g., gas cylinders) through one or more respective valves 202. In various embodiments, the valve(s) 202 are fixed orifices, needle valves, mass flow controllers (MFCs), other suitable flow controllers, or a combination thereof. The gas supplies 152 may supply nitrogen (N₂), such as at a pressure in a range of 1200 psi to 2200 psi, carbon dioxide (CO₂), such as at a pressure of around 870 psi, the like, or a combination thereof. A liquid 260 and a gas 270 are illustrated in the processing chamber 105. The pressure P_{Liquid} of the liquid 260 is equal to the pressure P_{Gas} of the gas 270, as both are in the same processing chamber 105.

FIG. 12 illustrates a graph of pressure versus time for a pressure 280 in the processing chamber 105. The pressure 280 increases over time as the processing chamber is pressurized to a pressure of, for example, 860 psi. The dilution of a gas into a liquid is a function of pressure, temperature, exposed area, and time. As such, the pressurization of the processing chamber 105 may lead to the dilution of the gas used to pressurize the processing chamber 105 into a liquid in the processing chamber 105. It may be desirable to avoid the mixing of the pressurizing gas and liquids in order to reduce or eliminate undesirable gas introduction, which could negatively effect the efficiency of rinsing or drying processes performed with the liquid.

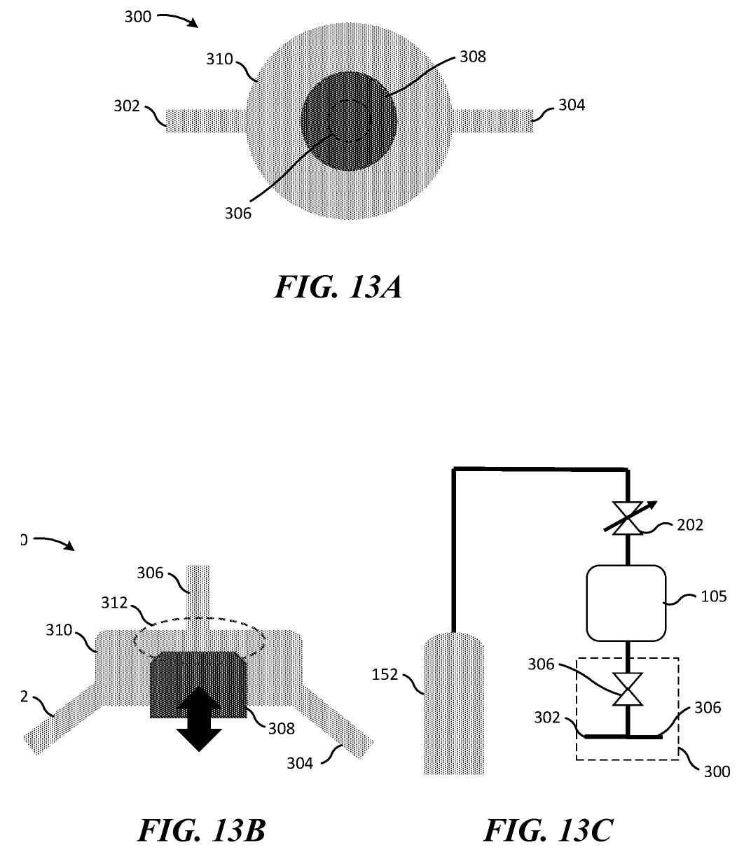

FIGS. 13A and 13B illustrate top and cross-sectional views, respectively, of a schematic diagram of a processing fluid valve 300. FIG. 13C illustrates the processing fluid valve 300 being coupled with the processing system 100.

As illustrated by FIGS. 13A and 13B, the processing fluid valve 300 comprises a first port 302, a second port 304, and a third port 306 coupled with a chamber 310. The first port 302 is coupled with a liquid input line (e.g., a line coupled with a processing fluid 230 such as IPA), the second port 304 is coupled with a liquid output line for removing, recovering, or recycling the liquid, and the third port 306 is coupled to a gas tank (such as through a coupling with the processing chamber 105. A plug 308 may be raised and lowered to open and close the third port 306 by controlling the surface area accessible to the third port 306 in the region 312. FIG. 13C illustrates the processing fluid valve 300 coupled with the processing chamber 105 of the processing system 100, with the third port 306 illustrated as a valve. The processing fluid valve 300 may be advantageous by enabling control over the pressurization of the processing fluid 230, which may be useful for reducing or eliminating damaging gas bubbles in liquid-carrying lines.

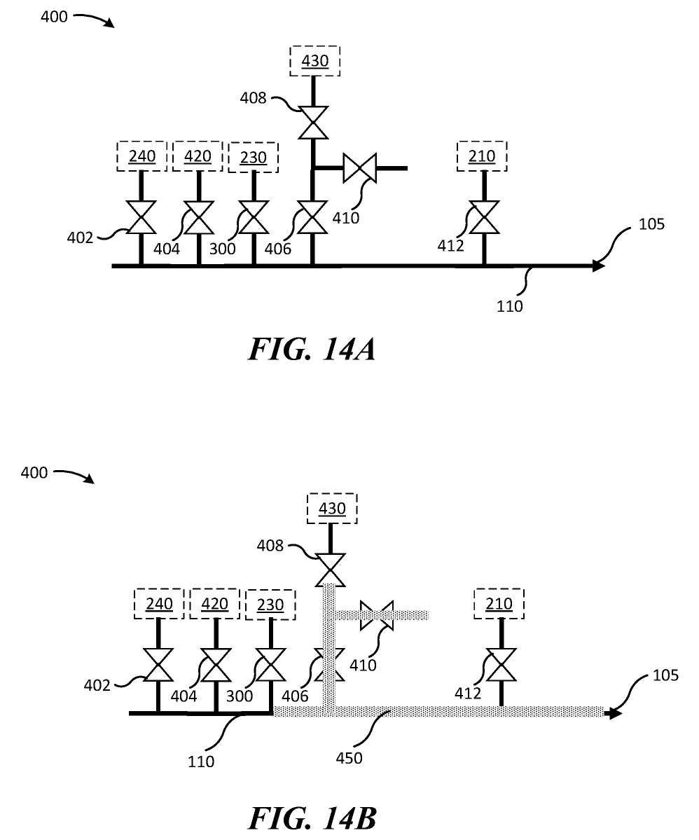

FIGS. 14A and 14B illustrate a valve system 400 for supplying gases and liquids to a processing system (e.g., the processing system 100; see above, FIG. 1) through a supply line 110, in accordance with some embodiments. Valve 402 is coupled with a dry fluid 240 (e.g., liquid CO₂), valve 404 is coupled with a pressurizing gas 420 (e.g., CO₂ or N₂ at a pressure in a range of 860 psi to 1200 psi), processing fluid valve 300 (see above, FIGS. 17A-C) is coupled with a processing fluid 230 (e.g., liquid IPA), valve 412 is coupled with an etch chemistry 210, and valve 406 is coupled through valve 408 with a purging gas 430 (e.g., CO₂ or N₂ at a pressure in a range of 1 atmosphere to 860 psi). The valves 402, 404, 406, 412, and the processing fluid valve 300 are coupled with a supply line 110 that is further coupled with a processing chamber (e.g., the processing chamber 105; see above, FIG. 1), such as through an opening 135; see above, FIG. 1. Although not illustrated, another valve may couple the supply line 110 with a source of deionized (DI) water. In some embodiments, the valves are arranged along the supply line 110 from a furthest position from the processing chamber 105 to a closest position to the processing chamber 105 in the order of valve 402, valve 404, processing fluid valve 300, valve 406, and valve 412. A node between the valves 406 and 408 may be further coupled to a drain.

In some embodiments, the valve system 400 may be used to perform one or more methods for wavefront processing of a substrate, as described above with respect to FIGS. 2-10. For example, the processing chamber 105 may have been purged with a purge liquid 220 and is subsequently filled with the processing fluid 230, as described above with respect to FIG. 12. After the purge with the processing fluid 230 is complete, the processing fluid valve 300 is closed.

Next, the pressure in the processing chamber 105 may be ramped up (for example, to around 860 psi) by opening valves 408 and 406 and closing valve 410 to pressurize the chamber with the purging gas 430 (e.g., CO₂ or N₂). Valve 406 is then closed. In some embodiments, the temperature in the processing chamber 105 is kept in a range of 40 ºC to 50 ºC to support a supercritical condition of a subsequently added fluid.

In a next step, the valve 402 is opened to deliver the dry fluid 240 (e.g., liquid CO₂ from a bottom of a CO₂ cylinder or other supply) into the processing chamber 105. Pressure in the processing chamber 105 supports the liquid phase of the dry fluid 240. All of the processing fluid 230 is displaced by the dry fluid 240, such as in a wavefront pulse as described above with respect to FIG. 9. In some embodiments, the dry fluid 240 is pulsed in an injection to fill the processing chamber 105, then valve 402 is closed to allow residual processing fluid 230 to dissolve into the dry fluid 240, and then valve 402 is opened to allow another pulse of the dry fluid 240 to enter the processing chamber 105. This pulse-pause-pulse cycle may be repeated for any suitable number of cycles.

Next, the pressure in the processing chamber 105 may be raised (such as to a pressure in a range of 1100 to 1200 psi) by opening valve 404 and allowing the pressurizing gas 420 (e.g., N₂ from a gas cylinder or CO₂ from a compressor) to pressurize the processing chamber 105. This may bring the dry fluid 240 to a supercritical condition as a supercritical fluid 242, as described above with respect to FIG. 10. In various embodiments, the temperature in the processing chamber is raised, such as to around 90 ºC, to allow for improved supercritical processing. In some embodiments, vapor of the processing fluid 230 (e.g., IPA vapor) is further injected into the processing chamber 105 to reduce evaporation of the processing fluid 230.

The length of the supply line 110 may restrict the amount of the pressurizing gas 420 that dissolves in the processing chamber 105. A final valve on the supply line 110, such as a valve 202 (see above, FIG. 11) between valve 412 and the processing chamber 105, can be closed and isolate the mixed area of the supply line 110 that may contain pressurizing gas 420 mixed with residual processing fluid 230, residual dry fluid 240, the like, or a combination thereof. The contents of the mixed area upstream of the final valve may then be purged away.

In a next step, pressure in the processing chamber 105 is lowered so that the supercritical fluid 242 (e.g., supercritical CO₂) becomes a gas (e.g., gaseous CO₂). The processing chamber 105 is then fully vented.

FIG. 14B illustrates the valve system 400 in an arrangement to reduce or eliminate gas introduction, such as damaging bubbles, into liquid-carrying lines. Valves 402, 404, 408, and 412 are closed while processing fluid valve 300 is open to allow the processing fluid 230 to flow to the processing chamber 105. As such, the processing fluid 230 flows along the lines of region 450. Valves 406 and 410 are opened to allow the processing fluid 230 to flow to a drain. Next, valve 406 is closed so that processing fluid 230 fills the lines between valves 406 and 408 and no damaging meniscus that could cause structure collapse forms when the purging gas 430 is subsequently passed into the line 401. In some embodiments, similar arrangements of coupling a valve to a drain between two valves that couple a gas supply to the line 401 are present and are used for any suitable gas supply, thereby reducing damaging bubble formation.

FIG. 15 illustrates a process flow chart diagram of a method 800 for processing a substrate, in accordance with some embodiments. In step 802, a processing fluid is dispensed onto the substrate in a processing chamber from an opening through an upper surface of the processing chamber, as described above with respect to FIGS. 4 and 8. The opening is near an edge of the substrate. In step 804, the processing fluid is displaced in the processing chamber with a dry fluid injected through the opening as a wavefront pulse, as described above with respect to FIGS. 5 and 9. The dry fluid displacing the processing fluid through a conduit opposite the opening.

FIG. 16 illustrates a process flow chart diagram of a method 900 for processing a substrate, in accordance with some embodiments. In step 902, an etch chemistry is dispensed into a processing space, as described above with respect to FIG. 2. The processing space holds the substrate. In step 904, the etch chemistry is displaced through the processing space with a wavefront pulse of deionized water, as described above with respect to FIG. 3. In step 906, the deionized water is displaced through the processing space with a wavefront pulse of isopropyl alcohol (IPA), as described above with respect to FIGS. 4 and 8. In step 908, the IPA is displaced through the processing space with a wavefront pulse of liquid carbon dioxide (CO2), as described above with respect to FIGS. 5 and 9.

Example embodiments of the invention are described below. Other embodiments can also be understood from the entirety of the specification as well as the claims filed herein.

Example 1. A method for processing a substrate, the method including: dispensing a processing fluid onto the substrate in a processing chamber from an opening through an upper surface of the processing chamber, the opening near an edge of the substrate; and displacing the processing fluid in the processing chamber with a dry fluid injected through the opening as a wavefront pulse, the dry fluid displacing the processing fluid through a conduit opposite the opening.

Example 2. The method of example 1, further including bringing the dry fluid to a supercritical state after displacing the processing fluid.

Example 3. The method of one of examples 1 or 2, where the processing fluid includes isopropyl alcohol.

Example 4. The method of one of examples 1 to 3, where the dry fluid includes carbon dioxide.

Example 5. The method of one of examples 1 to 4, where dispensing the processing fluid onto the substrate displaces deionized water previously dispensed into the processing chamber.

Example 6. The method of example 5, where the deionized water displaces an etch chemistry previously dispensed into the processing chamber.

Example 7. The method of example 6, where the etch chemistry, the deionized water, the processing fluid, and the dry fluid are present within the processing chamber at a same time.

Example 8. A method for processing a substrate, the method including: dispensing an etch chemistry into a processing space, the processing space holding the substrate; displacing the etch chemistry through the processing space with a wavefront pulse of deionized water; displacing the deionized water through the processing space with a wavefront pulse of isopropyl alcohol (IPA); and displacing the IPA through the processing space with a wavefront pulse of liquid carbon dioxide (CO2).

Example 9. The method of example 8, where the wavefront pulses are dispensed into the processing space through an opening in an upper surface of the processing space.

Example 10. The method of one of examples 8 or 9, further including displacing the liquid carbon dioxide through the processing space with a wavefront pulse of nitrogen gas.

Example 11. The method of one of examples 8 to 10, further including bringing the liquid carbon dioxide to a supercritical state after displacing the IPA.

Example 12. The method of example 11, further including venting the supercritical state of carbon dioxide from the processing space as gaseous carbon dioxide.

Example 13. The method of one of examples 8 to 12, where the etch chemistry, the deionized water, the IPA, and the liquid CO2 are present in the processing space at a same time.

Example 14. A processing system including: a processing chamber including an opening in an upper surface of the processing chamber, the opening being coupled to respective supplies of a processing fluid and a dry fluid, the processing chamber being configured to: receive a substrate in a processing space within the processing chamber; dispense a processing fluid over the substrate from the opening; and displace the processing fluid with a wavefront pulse of a dry fluid from the opening.

Example 15. The processing system of example 14, where the processing fluid includes isopropyl alcohol (IPA).

Example 16. The processing system of example 15, where a supply of IPA is coupled to the processing chamber through a processing fluid valve, the processing fluid valve including: a chamber; a first port coupled between the chamber and the supply of IPA; a second port coupled between the chamber and the processing chamber; and a plug configured to open and close the second port by being raised and lowered.

Example 17. The processing system of example 16, where the processing fluid valve further includes a third port coupled between the chamber and a liquid output line.

Example 18. The processing system of one of examples 14 to 17, further including: a supply line coupled with the processing chamber; a first valve coupled between a processing fluid supply and the supply line; a second valve coupled between the supply line and a gas supply, the second valve being coupled to the supply line closer to the processing chamber than the first valve; a third valve coupled between the second valve and the gas supply, a node being between the second valve and the third valve; and a fourth valve being coupled between the node and a drain.

Example 19. The processing system of one of examples 14 to 18, where the dry fluid includes liquid carbon dioxide.

Example 20. The processing system of one of examples 14 to 19, where the processing chamber is further configured to bring the dry fluid to a supercritical state.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for processing a substrate, the method comprising:
dispensing a processing fluid onto the substrate in a processing chamber from an opening through an upper surface of the processing chamber, the opening near an edge of the substrate; and
displacing the processing fluid in the processing chamber with a dry fluid injected through the opening as a wavefront pulse, the dry fluid displacing the processing fluid through a conduit opposite the opening.

2. The method of claim 1, further comprising bringing the dry fluid to a supercritical state after displacing the processing fluid.

3. The method of claim 1, wherein the processing fluid comprises isopropyl alcohol.

4. The method of claim 1, wherein the dry fluid comprises carbon dioxide.

5. The method of claim 1, wherein dispensing the processing fluid onto the substrate displaces deionized water previously dispensed into the processing chamber.

6. The method of claim 5, wherein the deionized water displaces an etch chemistry previously dispensed into the processing chamber.

7. The method of claim 6, wherein the etch chemistry, the deionized water, the processing fluid, and the dry fluid are present within the processing chamber at a same time.

8. A method for processing a substrate, the method comprising:
dispensing an etch chemistry into a processing space, the processing space holding the substrate;
displacing the etch chemistry through the processing space with a wavefront pulse of deionized water;
displacing the deionized water through the processing space with a wavefront pulse of isopropyl alcohol (IPA); and
displacing the IPA through the processing space with a wavefront pulse of liquid carbon dioxide (CO₂).

9. The method of claim 8, wherein the wavefront pulses are dispensed into the processing space through an opening in an upper surface of the processing space.

10. The method of claim 8, further comprising displacing the liquid carbon dioxide through the processing space with a wavefront pulse of nitrogen gas.

11. The method of claim 8, further comprising bringing the liquid carbon dioxide to a supercritical state after displacing the IPA.

12. The method of claim 11, further comprising venting the supercritical state of carbon dioxide from the processing space as gaseous carbon dioxide.

13. The method of claim 8, wherein the etch chemistry, the deionized water, the IPA, and the liquid CO₂ are present in the processing space at a same time.

14. A processing system comprising:
a processing chamber comprising an opening in an upper surface of the processing chamber, the opening being coupled to respective supplies of a processing fluid and a dry fluid, the processing chamber being configured to:
receive a substrate in a processing space within the processing chamber;
dispense a processing fluid over the substrate from the opening; and
displace the processing fluid with a wavefront pulse of a dry fluid from the opening.

15. The processing system of claim 14, wherein the processing fluid comprises isopropyl alcohol (IPA).

16. The processing system of claim 15, wherein a supply of IPA is coupled to the processing chamber through a processing fluid valve, the processing fluid valve comprising:
a chamber;
a first port coupled between the chamber and the supply of IPA;
a second port coupled between the chamber and the processing chamber; and
a plug configured to open and close the second port by being raised and lowered.

17. The processing system of claim 16, wherein the processing fluid valve further comprises a third port coupled between the chamber and a liquid output line.

18. The processing system of claim 14, further comprising:
a supply line coupled with the processing chamber;
a first valve coupled between a processing fluid supply and the supply line;
a second valve coupled between the supply line and a gas supply, the second valve being coupled to the supply line closer to the processing chamber than the first valve;
a third valve coupled between the second valve and the gas supply, a node being between the second valve and the third valve; and
a fourth valve being coupled between the node and a drain.

19. The processing system of claim 14, wherein the dry fluid comprises liquid carbon dioxide.

20. The processing system of claim 14, wherein the processing chamber is further configured to bring the dry fluid to a supercritical state.
